(19) United States
(12) Patent Application Publication
(10) Pub. No.: US 2009/0303333 A1
(43) Pub. Date: Dec. 10, 2009

(54) CAMERA AND IMAGE DETECTING MODULE THEREOF

(75) Inventors: Yaw-Ching Huang, Taichung (TW); Ming-Che Lee, Taichung (TW); Shou-Chy Chia, Taichung (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: ASIA OPTICAL CO., INC., Taichung (TW)

(21) Appl. No.: 12/475,632

(22) Filed: Jun. 1, 2009

(30) Foreign Application Priority Data
Jun. 5, 2008 (TW) 97120905

(51) Int. Cl. H04N 5/228; H01L 27/00

(52) U.S. Cl. 348/208.5; 250/208.1

(57) ABSTRACT

The invention provides an image detecting module including a base, a carrier movably disposed on the base, an image detecting unit, a driving unit, and a magnetic device fixed to the base, corresponding to the driving unit. The image detecting unit is fixed to one of the carrier and the base, and the driving unit is disposed fixed to the other of the carrier and the base. The carrier is substantially parallel to a plane, and the driving unit includes a coil to produce a variable induced magnetic force between the coil and the magnetic device. The driving unit and the magnetic device both have an angle with respect to the plane. The carrier and the image detecting unit are moved with respect to the base by the induced magnetic force between the coil and the magnetic device.

### CROSS REFERENCE TO RELATED APPLICATIONS

This Application claims priority of Taiwan Patent Application No. 097120905, filed on Jun. 5, 2008, the entirety of which is incorporated by reference herein.

### BACKGROUND OF THE INVENTION

1. Field of the Invention

The invention relates in general to an image detecting module and in particular to an image detecting module of a camera.

2. Description of the Related Art

Referring to FIG. 1, U.S. Pat. No. 5,266,988 discloses an image shake suppressing device for a camera. The image shake suppressing device is mounted in a lens 32. When using the camera, the angular velocity meters 33p and 33y measure the angular velocity of the moving camera and provide the measured data to a circuit. The driving parts 37p and 37y impel the lens 32 along a vertical optical axis, thereby compensating or suppressing blur due to vibration of the camera. However, this compensation method has limited compensation effect and may reduce image quality due to movement of the lens 32.

### BRIEF SUMMARY OF INVENTION

The invention provides an image detecting module including a base, a carrier movably disposed on the base, an image detecting unit, a driving unit, and a magnetic device fixed to the base, corresponding to the driving unit. The image detecting unit is fixed to one of the carrier and the base, and the driving unit is disposed fixed to the other of the carrier and the base. The carrier is substantially parallel to a plane, and the driving unit includes a coil to produce a variable induced magnetic force between the coil and the magnetic device. The driving unit and the magnetic device both have an angle with respect to the plane. The carrier and the image detecting unit are moved with respect to the base by the induced magnetic force between the coil and the magnetic device.

### BRIEF DESCRIPTION OF DRAWINGS

The invention can be more fully understood by reading the subsequent detailed description and examples with references made to the accompanying drawings, wherein:

FIG. 1 is a perspective diagram of a conventional image shake suppressing device for a camera;

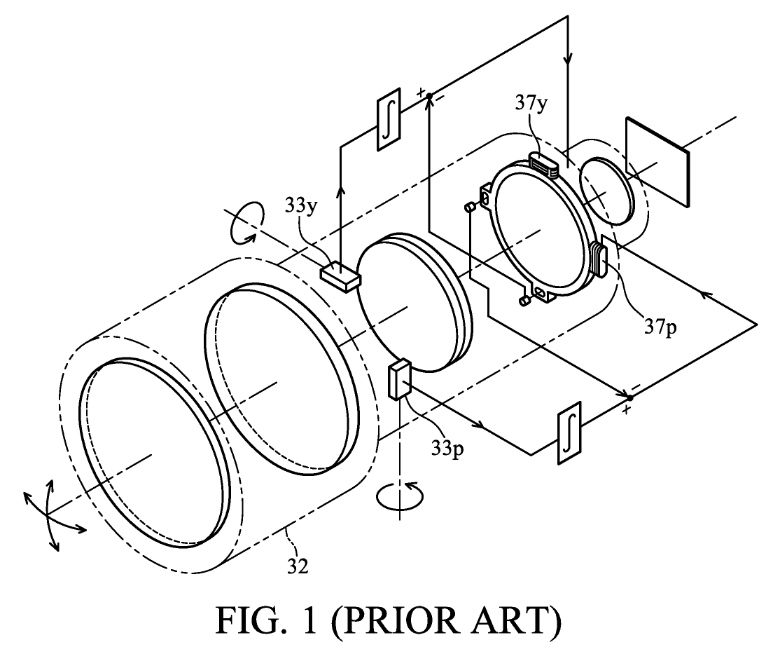

FIG. 2 is a perspective diagram of an image detecting module according to an embodiment of the invention;

FIG. 3 is a side view of the image detecting module in FIG. 2; and

FIG. 4 is a sectional view of a camera provided with the image detecting module in FIG. 2.

### DETAILED DESCRIPTION OF INVENTION

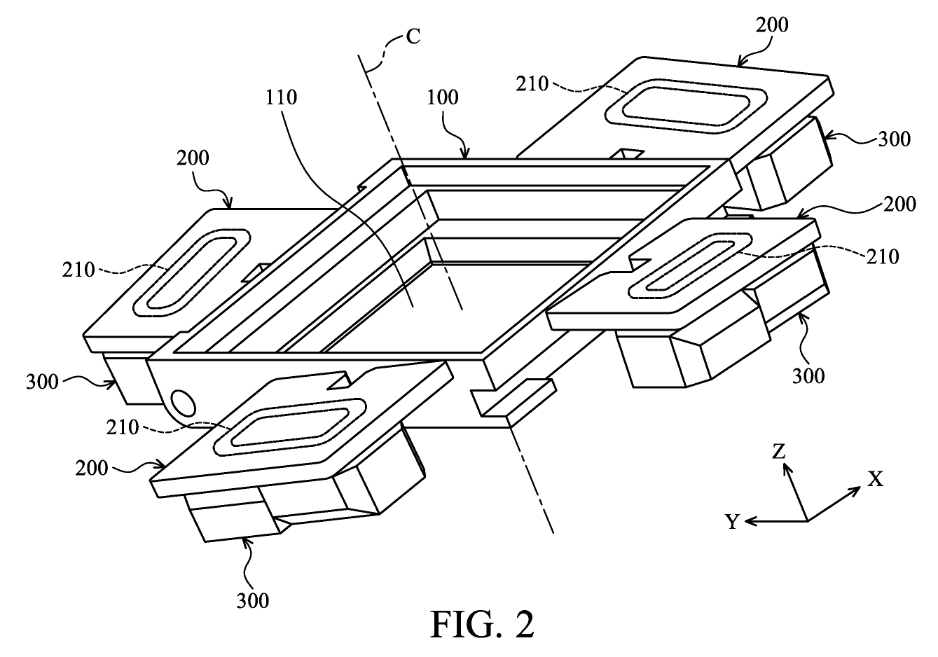

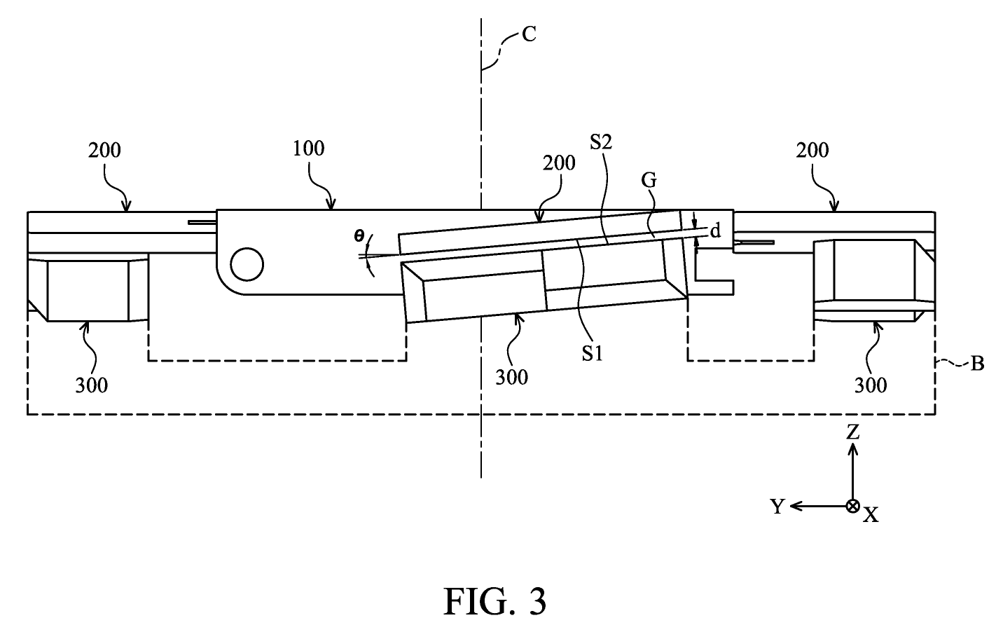

Referring to FIGS. 2 and 3, an embodiment of an image detecting module is disposed in a camera, comprising a rectangular carrier 100, a plurality of driving units 200, a plurality of magnetic devices 300 positioned corresponding to the driving units 200, and an image detecting unit (not shown) received in a space 110 of the carrier 100.

As shown in FIG. 2, the carrier 10 is substantially parallel to the XY plane defines a central axis C perpendicular to the XY plane. In this embodiment, the driving units 200 are fixed to four sides of the carrier 100, and each of the driving units 200 comprises a coil 210. As shown in FIG. 3, the magnetic devices 300 are disposed on the base B. Each of the magnetic devices 300 may comprise one or several permanent magnets, wherein the driving unit 200 and the magnetic device 300 are spaced apart at a distance d.

Referring to FIG. 3, the driving unit 200 comprises a first surface S1, and the magnetic device 300 comprises a second surface S2, opposite to the first surface S1. The first and second surfaces S1 and S2 are spaced apart at a distance d, and both of them have an angle θ (0°<θ<90°) with respect to the XY plane. In this embodiment, the four driving units 200 and magnetic devices 300 are provided at four sides of the carrier 100, symmetrical to the central axis C of the carrier 100.

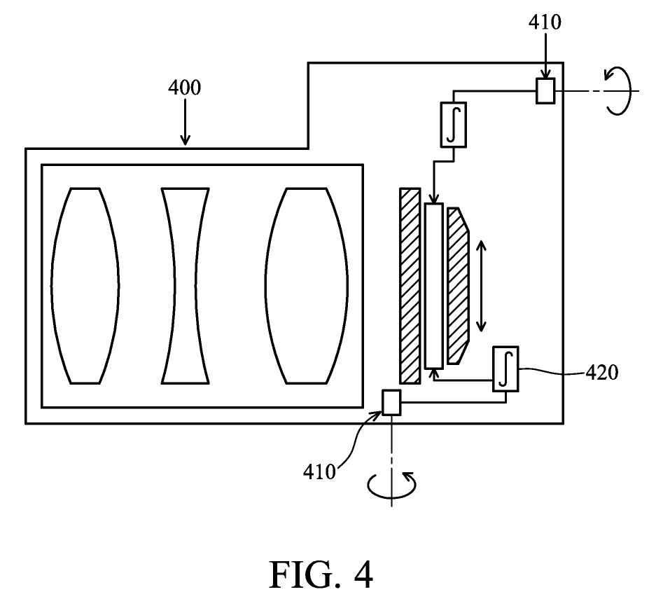

FIG. 4 is a sectional view of a camera 400 comprising the image detecting module in FIGS. 2 and 3. As shown in FIG. 4, the camera comprises at least a motion sensor 410 and a driving circuit 420. The motion sensor 410 may be angular acceleration element or linear acceleration element to detect vibration of the camera 400. The driving circuit 420 may be a PWM or digital circuit connecting to the motion sensor 410. When the photographer uses the camera and switches the image detecting module to a focusing or photography mode, the motion sensor 410 detects motion of the camera 400 caused by hand shake or movement of the photographer, and the driving circuit 420 provides a control current signal to the coil 210 of each driving unit 200. Hence, an electromagnetic field is induced by the coil 210 and interacts with the magnetic device 300, thereby producing magnetic force to impel the carrier 100 and the image detecting unit along X or Y axis for compensating or suppressing image blur caused by hand shake or movement of the photographer. In some embodiments, positions of the driving unit 200 and the magnetic device 300 can be exchanged. Namely, the driving units 200 can be disposed on the base B, and the magnetic devices 300 can be disposed on four sides of the carrier 100, opposite to the driving units 200.

The invention provides a camera and an image detecting module thereof for compensating or suppressing image blur caused by hand shake. Since the invention changes the position of the image detecting unit with respect to the optical axis rather than adjusting the lens position, image quality is not hindered. Furthermore, the image detecting module is moved perpendicular to the optical axis (parallel to the XY plane) by magnetic force between the coils and the magnetic devices which have a relatively smaller volume, facilitating miniaturization of the camera.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. An image detecting module, comprising:
a base;
a carrier, movably disposed on the base and substantially parallel to a plane;
an image detecting unit £ acts with the magnetic device, to generate an induced magnetic force between the coil and the magnetic device and impel the carrier and the image detecting unit with respect to the base.

2. The image detecting module as claimed in claim 1, wherein the carrier and the image detecting unit move parallel to the plane.

3. The image detecting module as claimed in claim 1, wherein the first and second surfaces are spaced apart at a distance.

4. The image detecting module as claimed in claim 1, further comprising a plurality of driving units and magnetic devices, wherein the carrier defines a central axis perpendicular to the plane, and the driving units and the magnetic devices are symmetric to the central axis.

5. The image detecting module as claimed in claim 1, further comprising four driving units and four magnetic devices corresponding to the driving units, wherein the carrier is rectangular, and the driving units and the magnetic devices are symmetrically arranged at four sides of the carrier.

6. An image detecting module, comprising:
a base;
a carrier, movably disposed on the base and substantially parallel to a plane;
an image detecting unit disposed on the base;
a driving unit fixed to the base, comprising a coil and a first surface having an angle with respect to the plane; and
a magnetic device fixed to the carrier and corresponding to the driving unit, comprising a second surface opposite to the first surface and having the angle with respect to the plane, wherein an electromagnetic field is induced by the coil and interacts with the magnetic device, to generate an induced magnetic force between the coil and the magnetic device and impel the carrier and the image detecting unit with respect to the base.

7. The image detecting module as claimed in claim 6, wherein the carrier and the image detecting unit move parallel to the plane.

8. The image detecting module as claimed in claim 6, wherein the first and second surfaces are spaced apart at a distance.

9. The image detecting module as claimed in claim 6, further comprising a plurality of driving units and magnetic devices, wherein the carrier defines a central axis perpendicular to the plane, and the driving units and the magnetic devices are symmetric to the central axis.

10. The image detecting module as claimed in claim 6, further comprising four driving units and four magnetic devices corresponding to the driving units, wherein the carrier is rectangular, and the driving units and the magnetic devices are symmetrically arranged at four sides of the carrier.

11. A camera, comprising:
a base;
a carrier, movably disposed on the base and substantially parallel to a plane;
an image detecting unit disposed on the base;
a driving unit fixed to the carrier, comprising a coil and a first surface having an angle with respect to the plane;
a magnetic device fixed to the base and corresponding to the driving unit, comprising a second surface opposite to the first surface and having the angle with respect to the plane;
a motion sensor, detecting motion of the camera; and
a driving circuit, connecting to the motion sensor and providing a control current signal to the coil, wherein an electromagnetic field is induced by the coil and interacts with the magnetic device, to generate an induced magnetic force between the coil and the magnetic device and impel the carrier and the image detecting unit with respect to the base.

12. The camera as claimed in claim 11, wherein the carrier and the image detecting unit move parallel to the plane.

13. The camera as claimed in claim 11, wherein the first and second surfaces are spaced apart at a distance.

14. The camera as claimed in claim 11, further comprising a plurality of driving units and magnetic devices, wherein the carrier defines a central axis perpendicular to the plane, and the driving units and the magnetic devices are symmetric to the central axis.

15. The camera as claimed in claim 11, further comprising four driving units and four magnetic devices corresponding to the driving units, wherein the carrier is rectangular, and the driving units and the magnetic devices are symmetrically arranged at four sides of the carrier.

16. A camera, comprising:
a base;
a carrier, movably disposed on the base and substantially parallel to a plane;
an image detecting unit disposed on the base;
a driving unit fixed to the base, comprising a coil and a first surface having an angle with respect to the plane;
a magnetic device fixed to the carrier and corresponding to the driving unit, comprising a second surface opposite to the first surface and having the angle with respect to the plane;
a motion sensor, detecting motion of the camera; and
a driving circuit, connecting to the motion sensor and providing a control current signal to the coil, wherein an electromagnetic field is induced by the coil and interacts with the magnetic device, to generate an induced magnetic force between the coil and the magnetic device and impel the carrier and the image detecting unit with respect to the base.

17. The camera as claimed in claim 16, wherein the carrier and the image detecting unit move parallel to the plane.

18. The camera as claimed in claim 16, wherein the first and second surfaces are spaced apart at a distance.

19. The camera as claimed in claim 16, further comprising a plurality of driving units and magnetic devices, wherein the carrier defines a central axis perpendicular to the plane, and the driving units and the magnetic devices are symmetric to the central axis.

20. The camera as claimed in claim 16, further comprising four driving units and four magnetic devices corresponding to the driving units, wherein the carrier is rectangular, and the driving units and the magnetic devices are symmetrically arranged at four sides of the carrier.
